(19) United States
(12) Patent Application Publication
(10) Pub. No.: US 2016/0027843 A1
(43) Pub. Date: Jan. 28, 2016

(54) SEMICONDUCTOR MEMORY DEVICE AND MANUFACTURING METHOD THEREOF

(71) Applicant: Yoshinori KUMURA, Seoul (KR)

(72) Inventor: Yoshinori KUMURA, Seoul (KR)

(21) Appl. No.: 14/629,023

(22) Filed: Feb. 23, 2015

Related U.S. Application Data
(60) Provisional application No. 62/029,083, filed on Jul. 25, 2014.

(51) Int. Cl. H01L 27/22; H01L 29/66; H01L 43/10; H01L 43/12; H01L 43/02; H01L 43/08

(52) U.S. Cl. CPC H01L 27/228; H01L 43/02; H01L 43/08; H01L 43/10; H01L 43/12; H01L 29/66568

(57) ABSTRACT

According to one embodiment, a semiconductor memory device includes a magnetic tunnel junction (MTJ) element, a contact layer and a first material layer. The contact layer is provided under the MTJ element and comprises a first material. The first material layer is provided around the contact layer and comprises the first material or an oxide of the first material.

### CROSS-REFERENCE TO RELATED APPLICATIONS

This application claims the benefit of U.S. Provisional Application No. 62/029,083, filed Jul. 25, 2014, the entire contents of which are incorporated herein by reference.

### FIELD

Embodiments described herein relate generally to a semiconductor memory device applicable to, for example, a magnetoresistive random access memory (MRAM), and a method of manufacturing such a device.

### BACKGROUND

An MRAM is a general term for nonvolatile semiconductor memories which utilize change in the resistance of the barrier layer depending on the magnetization direction of the ferromagnetic material. A memory cell of an MRAM comprises a magnetic tunnel junction (MTJ) resistance element and a transistor. A bottom electrode contact plug (referred to as a bottom contact plug hereinafter) is formed on one diffusion layer of the transistor, and an MTJ element is formed on the bottom contact plug. The magnetic properties of a MTJ element are dependent on the flatness of the material which is underneath.

### BRIEF DESCRIPTION OF THE DRAWINGS

FIG. 1 is a plan view showing an example of a semiconductor memory device according to the first embodiment;

FIG. 2 is a cross-sectional view taken along line II-II of FIG. 1;

FIG. 3 is a cross-sectional view showing a method of manufacturing the semiconductor memory device according to the first embodiment;

FIG. 4 is a cross-sectional view showing a processing step following that of FIG. 3;

FIG. 5 is a cross-sectional view showing a processing step following that of FIG. 4;

FIG. 6 is a cross-sectional view showing a processing step following that of FIG. 5;

FIG. 7 is a cross-sectional view showing a processing step following that of FIG. 6;

FIG. 8 is a cross-sectional view showing a processing step following that of FIG. 7;

FIG. 9 is a cross-sectional view showing a processing step following that of FIG. 8;

FIG. 10 is a cross-sectional view showing a modified example of the first embodiment;

FIG. 11 is a cross-sectional view showing a method of manufacturing the semiconductor memory device according to the modified example of the first embodiment;

FIG. 12 is a cross-sectional view showing a processing step following that of FIG. 11;

FIG. 13 is a cross-sectional view showing a processing step following that of FIG. 12;

FIG. 14 is a cross-sectional view showing a processing step following that of FIG. 13;

FIG. 15 is a plan view showing an example of a semiconductor memory device according to the second embodiment;

FIG. 16 is a cross-sectional view showing a modified example of the second embodiment;

FIG. 17 is a plan view showing an example of a semiconductor memory device according to the third embodiment; and

FIG. 18 is a cross-sectional view showing a modified example of the third embodiment.

### DETAILED DESCRIPTION

In general, according to one embodiment, a semiconductor memory device includes a magnetic tunnel junction (MTJ) element, a contact layer and a first material layer. The contact layer is provided under the MTJ element and comprises a first material. The first material layer is provided around the contact layer and comprises the first material or an oxide of the first material.

Embodiments will now be described with reference to the drawings, identical parts being designated by the same reference numbers or symbols.

### First Embodiment

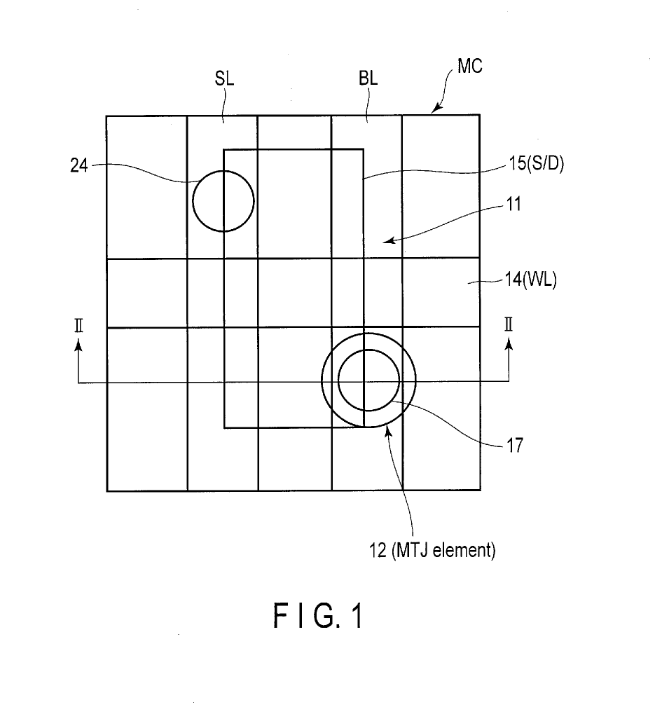

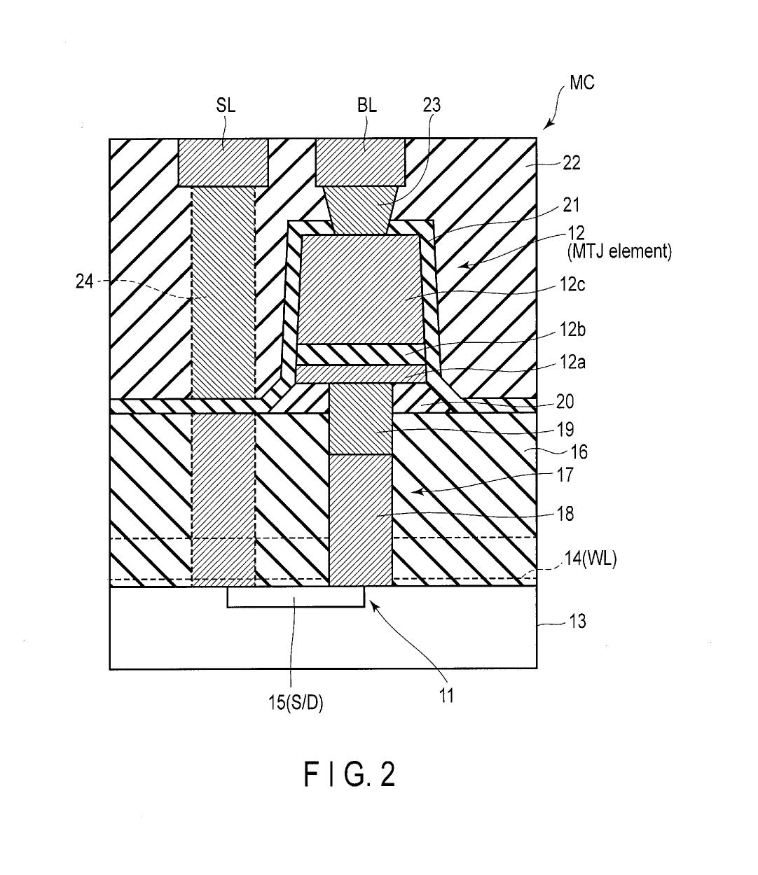

FIGS. 1 and 2 each show a semiconductor memory device according to the first embodiment, that is, for example, a memory cell MC of an MRAM. The memory cell MC comprises a transistor 11 and an MTJ element 12. For example, inside a silicon substrate 13, a shallow trench isolation (STI) region is formed as an element separation region not shown in the figures. A gate electrode 14 of the transistor 11 is formed on the substrate 13 via a gate insulating film also not shown. The gate electrode is connected to a gate electrode of another memory cell (not shown) adjacent in a row direction, thus constituting a word line WL. In the substrate 13 located on both sides of the gate electrode 14, diffusion layers 15 which constitute source-drain (S/D) regions are formed.

An interlayer insulating film 16 which covers the transistor 11 is formed on the substrate 13. Within the interlayer insulating film 16, a bottom contact plug 17 is formed as a contact layer electrically connected to one of the diffusion layers 15, which constitutes a source or drain region. The bottom contact plug 17 comprises a first contact 18 and a second contact 19. The first contact 18 is formed of, for example, tungsten (W) or titanium nitride (TiN). The second contact 19 is formed on the first contact 18.

The second contact 19 is formed of, for example, tantalum (Ta). Note that the material of the second contact 19 is not limited to Ta, but it is also possible to apply one of such metals as Ti, Cu, Hf, W, Al, Ni and Co, or Si, or a compound of B and at least one of Ta, Ti, Cu, Hf, W, Al, Ni and Co. The surface of the second contact 19 is higher than that of the interlayer insulating film 16. The first material layer 20 is formed around the second contact 10 and on the surface of the interlayer insulating film 16. The first material layer 20 is formed of the same material as that of the second contact 19 or an oxide of that material. That is, when the second contact 19 is formed of tantalum, the first material layer 20 is a tantalum oxide (TaOx) film. Or when the second contact 19 is formed of hafnium, the first material layer 20 is a hafnium oxide (HfOx) film. The surface of the first material layer 20 is flush with the surface of the second contact 19 to form a flat surface together with the surface of the second contact 19.

The MTJ element 12 is formed on the second contact 19 and the first material layer 20. The upper surface of the second contact 19 is smaller than the bottom surface of the MTJ element. With this structure, the memory cell MC can be miniaturized.

The MTJ element 12 comprises, for example, a ferromagnetic layer 12a, a barrier layer 12b as a non-magnetic layer, and a ferromagnetic layer 12c. Of ferromagnetic layers 12a and 12c, one in which the magnetization direction is fixed is called the fixed layer, whereas one in which the magnetization direction is inversed with an external magnetic field or STT is called the free layer. In this embodiment, the MTJ element 12 is of a three-layered structure; however, the element is not limited to the three-layered structure, but may be modified into various versions. That is, for example, the free layer or fixed layer may comprise a cap layer. Or, the element may take such a structure that the one of interfaces of the fixed layer which does not border the barrier layer, is placed to border the ferromagnetic layer. Or, the fixed layer may comprise the first ferromagnetic layer, a ruthenium (Ru) layer and the second ferromagnetic layer. Or even, the MTJ element 12 may comprise a first fixed layer, a first barrier layer, a free layer, a second barrier layer and a second fixed layer.

The MTJ element 12 is covered by a protective film 21 made of, for example, silicon nitride or alumina. An insulating film 22 is formed on the protective film 21, and an top contact plug 23, which is connected to the MTJ element 12, is formed in the insulating film 22 and partly in the protective film 21. A bit line BL is formed on the top contact plug 23. The bit line BL is arranged in a direction orthogonal to the word line WL.

On the other hand, a contact 24 is formed in the parts of the interlayer insulating film 16, the protective film 21 and the insulating film 22, which correspond to the other diffusion layer 15 which constitutes the other of the S/D regions. The contact 24 is electrically connected to the other diffusion layer 15 which constitutes the other one of the S/D regions. A source line SL is formed on the contact 24. The source line SL is arranged along the bit line BL.

(Processing Method)

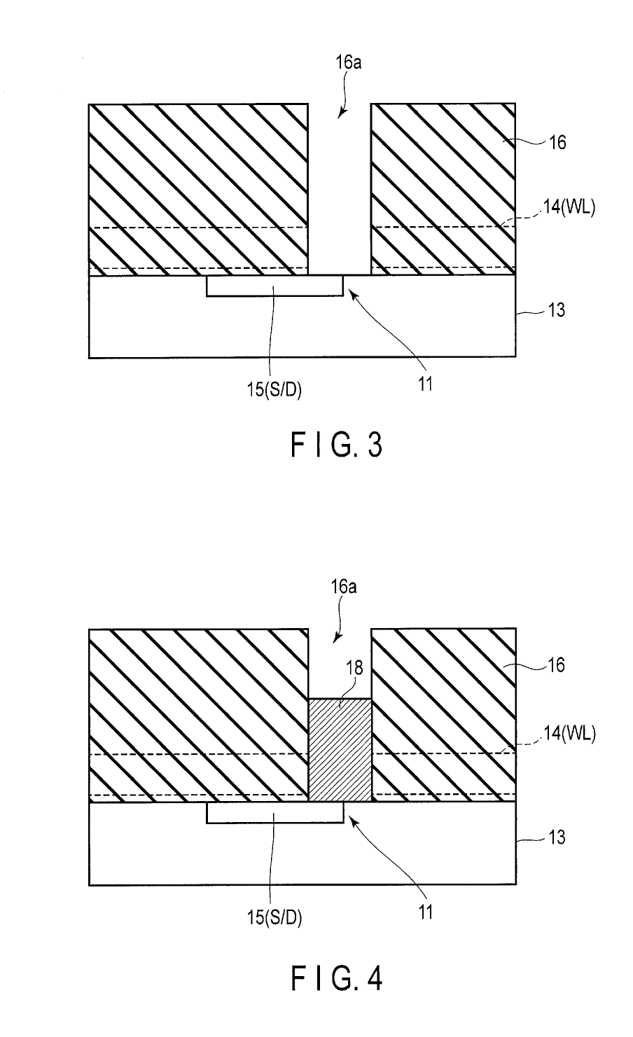

FIGS. 3 to 9 each show an example of the processing method of the bottom contact plug.

As shown in FIG. 3, the STI region, which is not shown, is formed in the silicon substrate 13, and the gate electrode 14 of the transistor 11 is formed on the silicon substrate 13. Further, the diffusion layers 15, which constitute the S/D regions, are formed to sandwich the gate electrode 14. Next, the interlayer insulating film 16 is deposited on the silicon substrate 13 and the transistor 11, and the surface of the interlayer insulating film 16 is planarized. As for the material of the interlayer insulating film 16, for example, a boron phosphorous silicate glass (BPSG) or plasma-tetra ethoxy silane (P-TEOS) or a laminated structure of one of these and a silicon nitride (SiN) film is applicable. Next, the interlayer insulating film 16 is selectively etched, and thus a contact hole 16a is opened, which exposes the diffusion layer 15 which constitutes the S or D region.

After that, as shown in FIG. 4, a metal material is filled into the contact hole 16a, and then planarized, thus forming the first contact 18. Applicable examples of the material of the first contact 18 are W and TiN. Further, the upper portion of the first contact 18 is etched back, and the surface of the first contact 18 is leveled lower than both surface portions of the interlayer insulating film 16 as shown in FIG. 4.

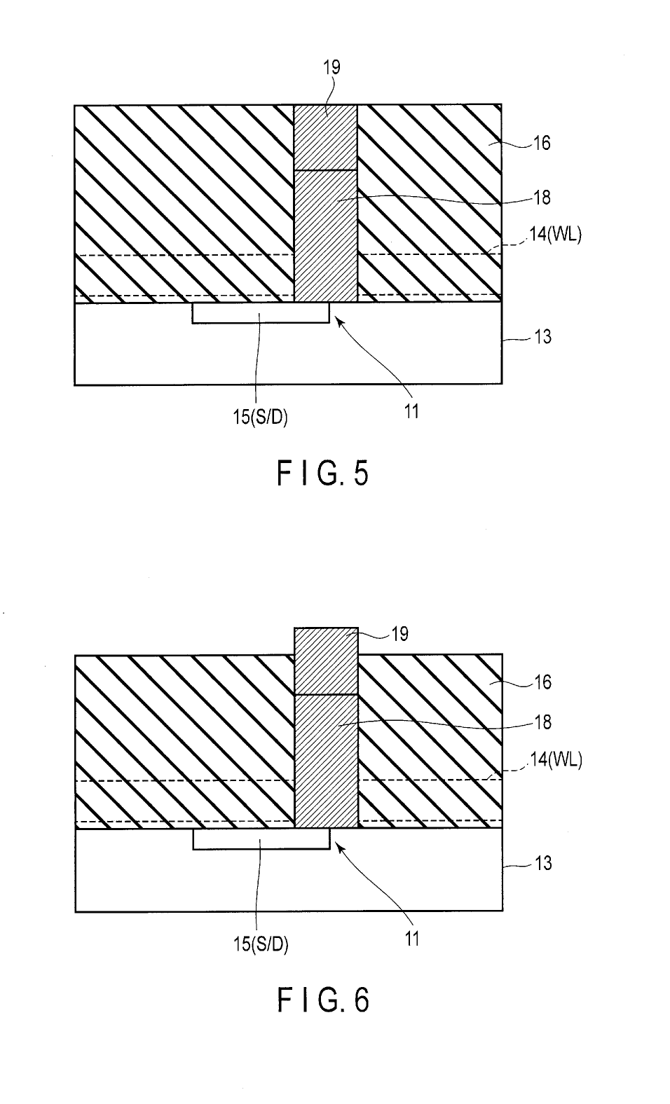

Next, as shown in FIG. 5, a material optimal for the characteristics of the MTJ element 12 is deposited on the entire surface and planarized, and the upper portion of the contact hole 16a is filled with the material, thereby forming the second contact 19. Applicable examples of the material of the second contact 19 are amorphous metals including Ta. But, as mentioned above, it is also possible to apply one of such metals as Ti, Cu, Hf, W, Al, Ni and Co, or Si, or a compound of B and at least one of Ta, Ti, Cu, Hf, W, Al, Ni and Co.

Next, as shown in FIG. 6, the interlayer insulating film 16 is selectively etched back, and thus side surfaces of the second contact 19 are exposed.

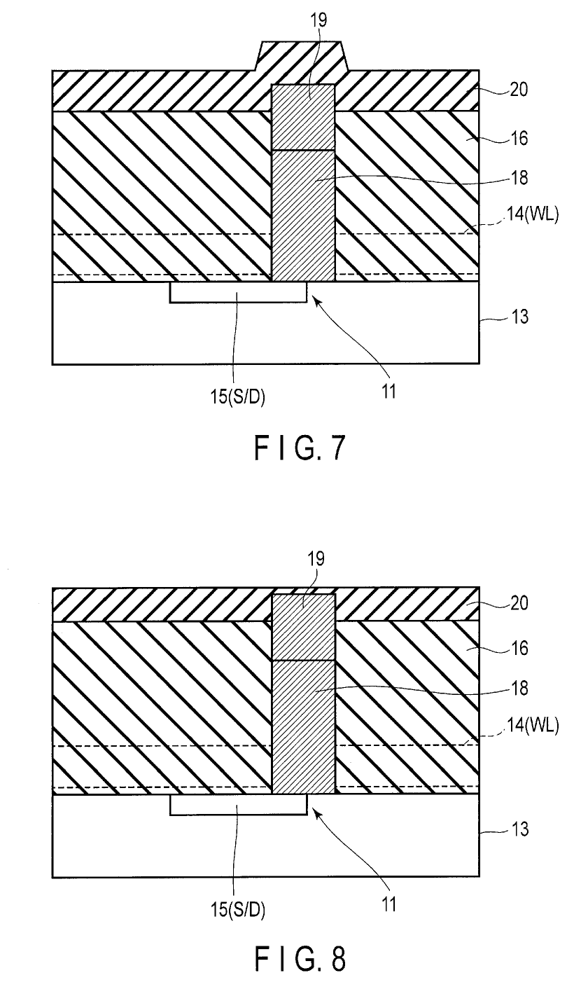

Next, as shown in FIG. 7, a material containing the same element as that of the second contact 19 or an oxide thereof is deposited as the first material layer 20 on the entire surface. More specifically, when the material of the second contact 19 is Ta, for example, TaOx is deposited as the first material layer 20. Or, when the second contact 19 is formed of Hf, the first material layer 20 is made of, for example, HfOx.

Subsequently, as shown in FIG. 8, the surface of the first material layer 20 is planarized by CMP, and the first material layer 20 is formed around the second contact 19. The material of the second contact 19 which constitutes the upper portion of the bottom contact plug 17 and the material around the second contact 19 are formed of the same element. Thus, in the flattening process by the CMP, it is possible to prevent dishing from occurring in the second contact 19 or the first material layer 20. Note that when the material of the second contact 19 is Ta, being easily oxidizable, the surface of the second contact 19 is naturally oxidized as the surface thereof is exposed by the flattening. Thus, a TaOx film is formed.

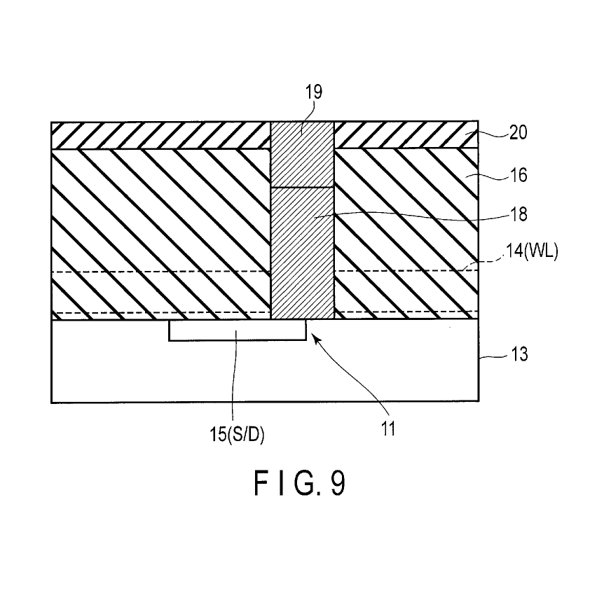

Next, as shown in FIG. 9, the oxide film (metal oxide) naturally formed on the surface of the second contact 19 is etched back by, for example, dry etching, and thus removed. In this embodiment, the material of the second contact 19 and the material of the first material layer 20 formed around the second contact 19 are made of the same element. Therefore, the etching rate in etching back the oxide film naturally formed on the surface of the second contact 19 is the same as the etching rate for the first material layer 20. Consequently, it is possible to prevent a step from being produced in the border between the second contact and the first material layer 20.

After that, the MTJ element 12 is formed on the second contact 19 and the first material layer 20. More specifically, on the second contact 19 and the first material layer 20 both of the surfaces already planarized, materials of ferromagnetic layers 12a and 12c and the barrier layer 12 are stacked one on another as shown in FIG. 2. With this structure, the deformation of ferromagnetic layers 12a and 12c and the barrier layer 12 can be prevented. After that, reactive ion etching (RIE) or ion beam etching (IBE) is carried out using a hard mask not shown, and thus the materials of ferromagnetic layers 12a and 12c and the barrier layer 12 are etched. At the same time, the first material layer 20 is etched as well. Note that the MTJ element 12 and the manufacturing process from then on are not essential to this embodiment, and therefore the further detailed descriptions will be omitted.

According to the first embodiment, the material of the second contact 19 which constitute the upper portion of the bottom contact plug 17 is made of the same element as that of the first material layer 20 formed around the second contact 19. Therefore, it is possible to prevent dishing from occurring in the surfaces of the second contact 19 and the first material layer 20 during the CMP process. Further, the materials of the second contact 19 and the first material layer 20 are formed of the same element, and therefore when the natural oxide film on the surface of the second contact 19 is etched back, it is possible to prevent a step from being produced in the border between the second contact 19 and the first material layer 20. Thus, the MTJ element 12 can be formed on a flat foundation of the second contact 19 and the first material layer 20. As a result, even when the upper surface of the second contact 19 is smaller in size than the bottom surface of the MTJ element 12, deformation of the barrier layer 12b in the MTJ element 12 can be prevented. Consequently, a short-circuit failure between ferromagnetic layers 12a and 12c or degradation of the magnetic properties, which reduces the coercive force Hc or the magneto-resistance ratio MR of the memory layer, can be prevented.

### Modified Example of First Embodiment

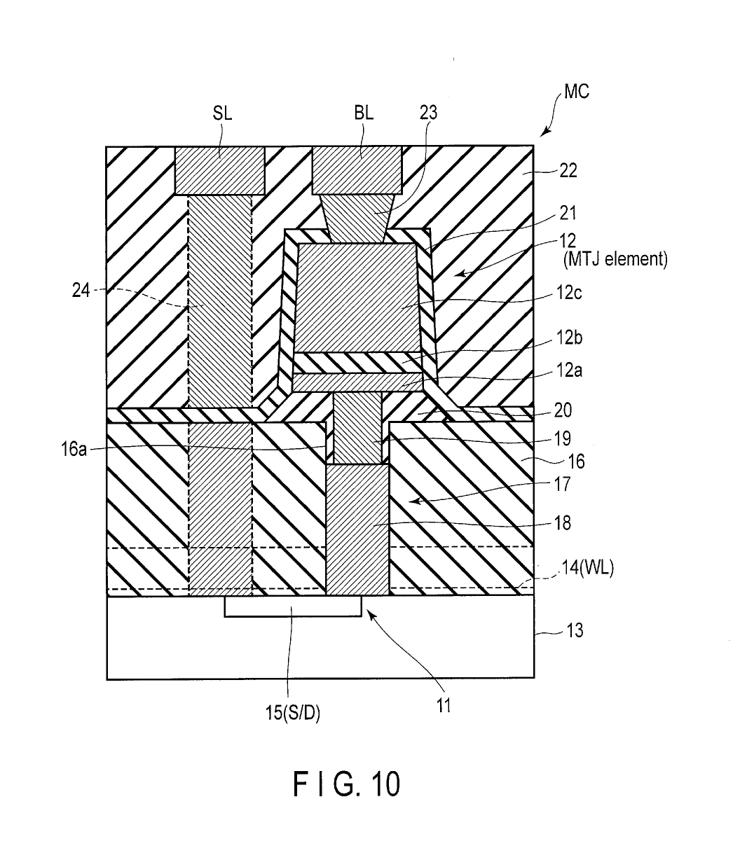

FIG. 10 shows a modified example of the first embodiment. In the first embodiment, the first material layer 20 is formed around the portion of the second contact 19, which is situated above the interlayer insulating film 16. By contrast, in this modified example, the first material layer 20 is formed also around the portion of the second contact 19, which is located within the contact hole 16a.

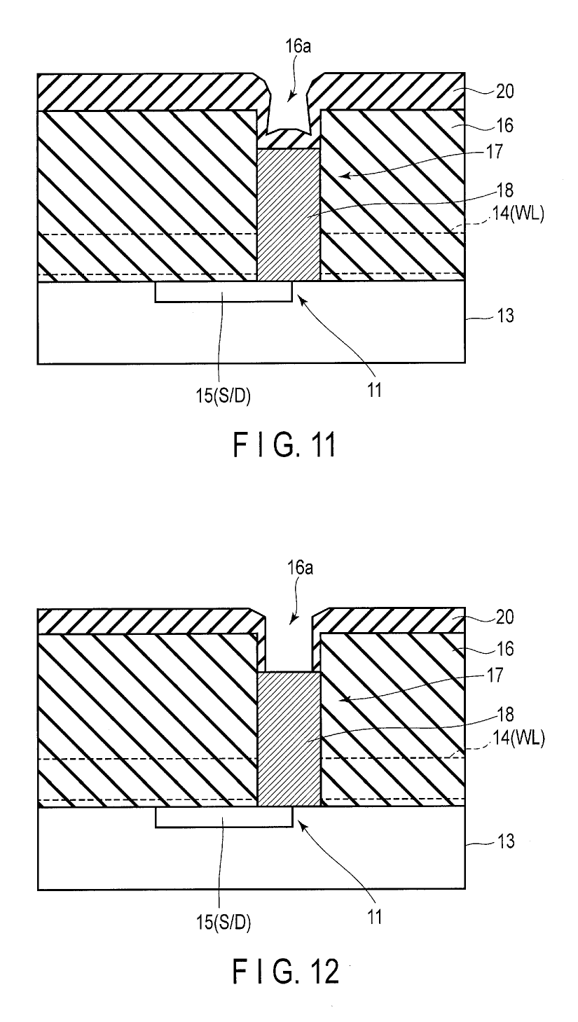

The structure shown in FIG. 10 can be formed by the processing steps shown in FIGS. 11 to 14. Note that the manufacturing steps up to FIG. 11 are the same as those shown in FIGS. 3 and 4.

Here, as shown in FIG. 11, after the first contact 18 in the contact hole 16a is etched back, the first material layer 20 is deposited on the entire surface. Consequently, the first material layer 20 is deposited on the side wall and bottom of the contact hole 16a. The material of the first material layer 20 is, for example, the same as or an oxide of that of the second contact 19 formed later.

Subsequently, as shown in FIG. 12, the first material layer 20 is etched back, and the portion of the first material layer 20, which is located on the bottom of the contact hole 16a, is removed.

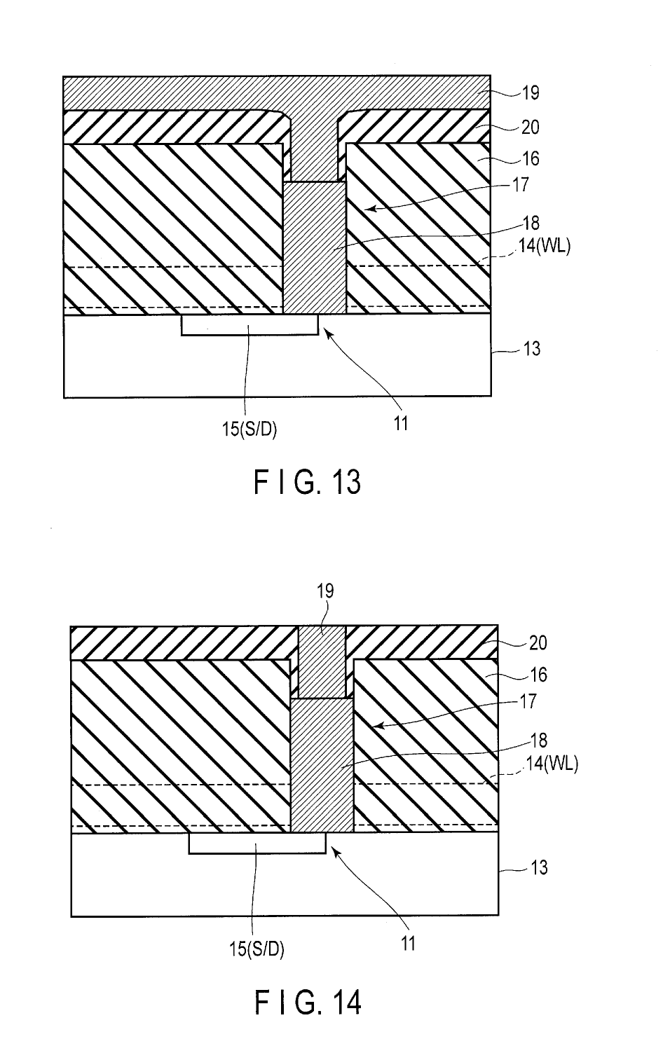

After that, as shown in FIG. 13, the material of the second contact 19 is deposited on the entire surface.

Then, as shown in FIG. 14, the second contact 19 is planarized by, for example, CMP. In this case as well, the material of the second contact 19 contains the same element as that of the material formed around the second contact 19. Consequently, it is possible to prevent dishing from occurring in the second contact 19 or the first material layer in the flattening process by CMP.

Further, since the material of the second contact 19 constituted by the same element as that of the first material layer 20, even when the natural oxide film formed on the surface of the second contact 19 is removed by etch back after the above-described step, it is possible to prevent a step from being produced in the border between the second contact 19 and the first material layer 20.

According to the above-discussed modified example as well, the MTJ element 12 can be formed on a flat foundation of the second contact 19 and the first material layer 20. As a result, even when the upper surface of the second contact 19 is smaller in size than the bottom surface of the MTJ element 12, deformation of the barrier layer 12b in the MTJ element 12 can be prevented. Consequently, a short-circuit failure between the ferromagnetic layers or degradation of the magnetic properties, which reduces the coercive force Hc or the magneto-resistance ratio MR of the memory layer, can be prevented.

### Second Embodiment

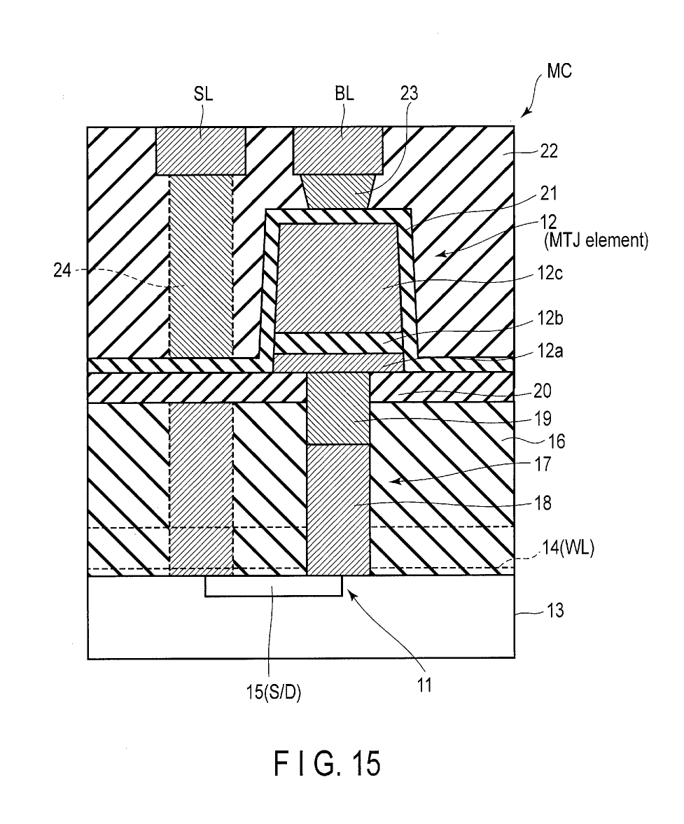

FIG. 15 shows a semiconductor memory device according to the second embodiment. In the first embodiment, the first material layer 20 is formed of the same material as or an oxide of that of the second contact 19. That is, the first material layer 20 contains a conductive material, and therefore when etching the ferromagnetic layer 12a, the barrier layer 12b and the ferromagnetic layer 12c using a hard mask, a part other than under the MTJ element 12 is removed.

By contrast, in the second embodiment, the first material layer 20 is formed of an oxide of the same material as that of the second contact 19. That is, the first material layer 20 is made of an insulator. Consequently, the first material layer 20 remains in the area other than under the MTJ element 12. In other words, the first material layer 20 is formed on the entire surface of the interlayer insulating film 16 around the second contact 19, and the protective film of the MTJ element 12 is formed on the first material layer 20 as well.

According to the second embodiment as well, it is possible to prevent a step from being produced in the border between the second contact 19 and the first material layer 20. Consequently, degradation in the characteristics of the MTJ element 12, which is formed on the second contact 19 and the first material layer 20, can be prevented.

### Modified Example of Second Embodiment

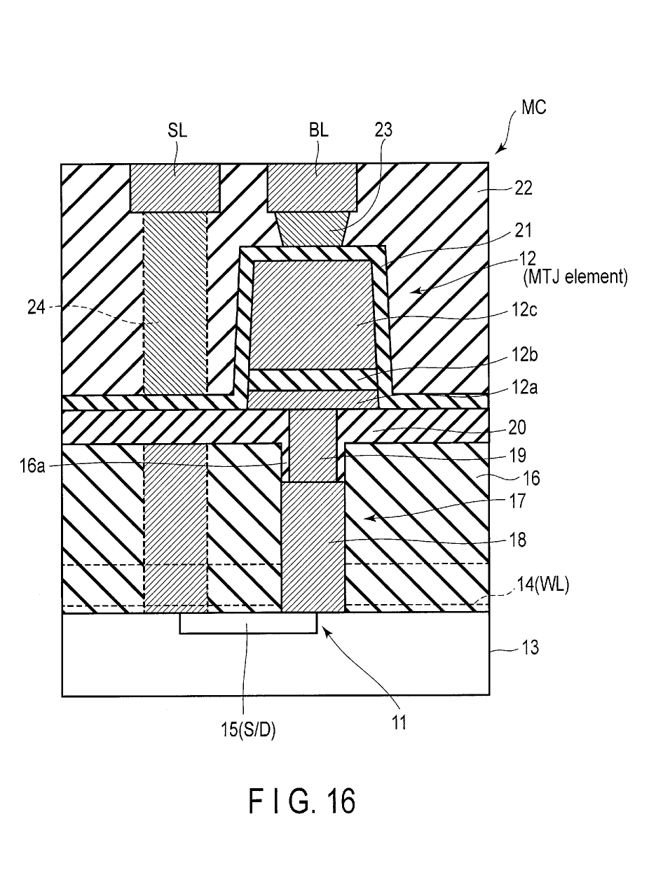

FIG. 16 shows a modified example of the second embodiment, and as in the case of the modified example of the first embodiment, the first material layer 20 is formed also around the portion of the second contact 19, which is located within the contact hole 16a.

According to this modified example, a similar effect to that of the second embodiment can be obtained.

### Third Embodiment

Each of the first and second embodiments and their modified examples discussed above is directed to the case where the upper surface of the second contact 19 is smaller than the bottom surface of the MTJ element 12.

On the other hand, the third embodiment will be described in connection with the case where the size of the upper surface of the second contact 19 is greater than or equal to that of the bottom surface of the MTJ element 12. That is, the size of the upper surface of the second contact 19 is not less than the size of the bottom surface of the MTJ element 12.

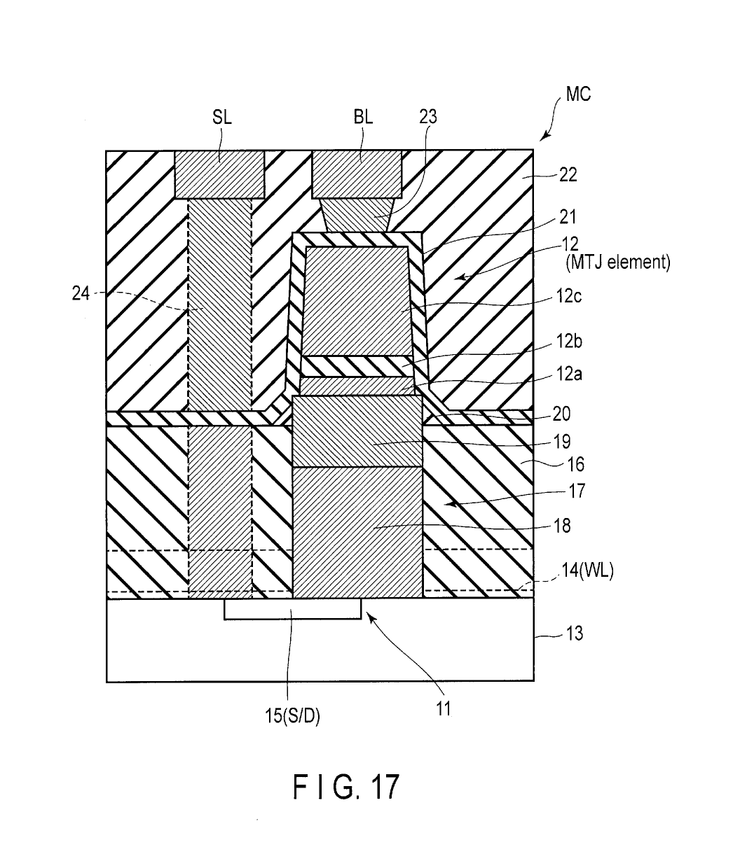

FIG. 17 shows the case where the upper surface of the first contact 18 and the second contact 19 which constitute the bottom contact plug 17 is, for example, made larger than the bottom of the MTJ element 12. The first material layer 20 is formed on the interlayer insulating film 16 such as to surround the second contact 19. The second material layer 20 is formed of the same material or an oxide thereof, as that of the second contact 19. With this structure, no dishing occurs in the upper surface of the second contact 19 when the second contact 19 and the first material layer 20 are planarized by CMP, or no step is produced in the border between the second contact 19 and the first material layer 20 when they are etched back. The MTJ element 12 is formed on the upper surface of the second contact 19. The MTJ element 12 is covered by the protective film 21.

The structure shown in FIG. 17 can be formed by processing steps similar to those of the first embodiment.

According to the third embodiment, the first material layer 20 is formed on the interlayer insulating film 16 such as to surround the second contact 19, and formed of the same material as or an oxide of that of the second contact 19. Therefore, it is possible to prevent dishing from occurring in the upper surface of the second contact 19 when the second contact 19 and the first material layer 20 are planarized by CMP. Thus, the upper surface of the second contact 19 is maintained to be flat. Further, since the upper surface of the second contact 19 is larger than the bottom of the MTJ element 12, the ferromagnetic layers 12a and 12c and the barrier layer 12b, which constitute the MTJ element 12, formed on the upper surface of the second contact 19 can be stacked parallel to each other. In this manner, deformation of the barrier layer 12b can be prevented. Consequently, a short-circuit failure between the ferromagnetic layers 12a and 12c or degradation of the magnetic properties, which reduces the coercive force Hc or the magneto-resistance ratio MR of the memory layer, can be prevented.

Further, since no step is formed in the border between the second contact 19 and the first material layer 20, the MTJ element 12, the second contact 19 and the first material layer 20 can be reliably covered by the protective film.

### Modified Example of Third Embodiment

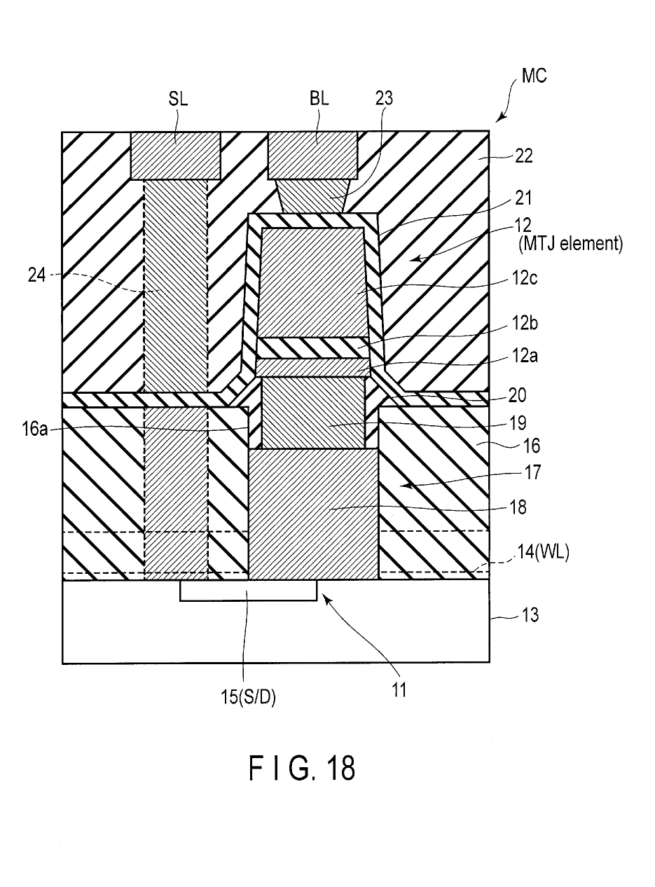

FIG. 18 shows a modified example of the third embodiment. In the third embodiment, the first material layer 20 is formed around the portion of the second contact 19, which is situated above the interlayer insulating film 16. By contrast, in this modified example, the first material layer 20 is formed also around the portion of the second contact 19, which is located within the contact hole 16a.

According to this modified example as well, it is possible to prevent a step from being produced in the border between the second contact 19 and the first material layer 20. Consequently, degradation in the characteristics of the MTJ element 12, which is formed on the second contact 19, can be prevented.

Note that in the third embodiment and in its modified example, when the first material layer 20 and the second contact 19 are formed of an oxide of the same material, the first material layer 20 can be retained without being etched as in the cases of the second embodiment and in its modified example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a magnetic tunnel junction (MTJ) element;
a contact layer provided under the MTJ element, the contact layer comprising a first material; and
a first material layer provided around the contact layer, the first material layer comprising the first material.

2. The device according to claim 1, wherein a level of a surface of the first material layer is equal to a level of a surface of the contact layer.

3. The device according to claim 1, wherein the first material is one metal of Ta, Cu, Hf, W, Al, Ni and Co, or Si, or a compound of B and at least one metal of Ta, Cu, Hf, W, Al, Ni and Co.

4. The device according to claim 1, wherein a surface of the contact layer is smaller in size than a bottom of the MTJ element.

5. The device according to claim 4, wherein the bottom of the MTJ element is provided on the surface of the contact layer and the surface of the first material layer.

6. The device according to claim 1, wherein the first material layer comprises an oxide of the first material and provided on the bottom of the MTJ element and a part other than the bottom of the MTJ element.

7. The device according to claim 2, wherein the surface of the contact layer is substantially equal in size to a bottom of the MTJ element.

8. A semiconductor memory device comprising:
a transistor provided in a semiconductor substrate, the transistor comprising source and drain regions and a gate electrode;
a contact layer provided on one of the source and drain regions of the transistor, the contact layer comprising a first material;
a first material layer provided around the contact layer, the first material layer comprising the first material; and
a magnetic tunnel junction (MTJ) element provided on at least the contact layer.

9. The device according to claim 8, wherein a level of a surface of the first material layer is equal to a level of a surface of the contact layer.

10. The device according to claim 8, wherein the first material is one metal of Ta, Ti, Cu, Hf, W, Al, Ni and Co, or Si, or a compound of B and at least one metal of Ta, Ti, Cu, Hf, W, Al, Ni and Co.

11. The device according to claim 8, wherein a surface of the contact layer is smaller in size than a bottom of the MTJ element.

12. The device according to claim 11, wherein the bottom of the MTJ element is provided on the surface of the contact layer and the surface of the first material layer.

13. The device according to claim 8, wherein the first material layer comprises an oxide of the first material and provided on the bottom of the MTJ element and a part other than the bottom of the MTJ element.

14. The device according to claim 9, wherein the surface of the contact layer is substantially equal in size to a bottom of the MTJ element.

15. A method of manufacturing a semiconductor memory device, the method comprising:
forming a transistor in a semiconductor substrate, the transistor comprising source and drain regions and a gate electrode;
forming a contact layer on one of the source and drain regions of the transistor, the contact layer comprising a first material;
forming a first material layer around the contact layer, the first material layer comprising the first material or an oxide of the first material; and
forming a magnetic tunnel junction (MTJ) element on the contact layer.

16. The method according to claim 15, wherein a level of a surface of the first material layer is equal to a level of a surface of the contact layer.

17. The method according to claim 15, wherein the first material is one metal of Ta, Ti, Cu, Hf, W, Al, Ni and Co, or Si, or a compound of B and at least one metal of Ta, Ti, Cu, Hf, W, Al, Ni and Co.

18. The method according to claim 15, wherein a surface of the contact layer is smaller in size than a bottom of the MTJ element.

19. The method according to claim 18, wherein the bottom of the MTJ element is formed on the surface of the contact layer and the surface of the first material layer.

20. The method according to claim 15, wherein the first material layer is formed of an oxide of the first material and formed on the bottom of the MTJ element and a part other than the bottom of the MTJ element.

21. The device according to claim 1, wherein
the first material layer is located within a bottom area of the MTJ element.
